(19) United States
(12) Patent Application Publication
(10) Pub. No.: US 2023/0311023 A1
(43) Pub. Date: Oct. 5, 2023

(54) RAW MATERIAL SUPPLY DEVICE AND RAW MATERIAL SUPPLY METHOD

(71) Applicant: Tokyo Electron Limited, Tokyo (JP)

(72) Inventor: Eiichi KOMORI, Yamanashi (JP)

(21) Appl. No.: 18/025,250

(22) PCT Filed: Sep. 2, 2021
(86) PCT No.: PCT/JP2021/032340

§ 371 Date: Mar. 8, 2023

(30) Foreign Application Priority Data
Sep. 15, 2020 (JP) 2020-154854

(51) Int. Cl. B01D 7/00; B01D 39/20

(52) U.S. Cl. CPC B01D 7/00; B01D 39/20; B01D 2253/311

(57) ABSTRACT

A raw material supply device according to an embodiment of the present disclosure generates a reactive gas from a solution obtained by dissolving a solid raw material in a solvent or a dispersion obtained by dispersing the solid raw material in a dispersion medium. The raw material supply device includes: a container configured to store the solution or the dispersion; an injector configured to inject the solution or the dispersion into the container; an exhaust port configured to evacuate an interior of the container; and a filter provided in the container and configured to partition the interior of the container into a plurality of regions including a first region in which the injector is provided and a second region in which the exhaust port is provided.

This is a National Phase application filed under 35 U.S.C. 371 as a national stage of PCT/JP2021/032340, filed Sep. 2, 2021, an application claiming the benefit of Japanese Application No. 2020-154854, filed Sep. 15, 2020, the content of each of which is hereby incorporated by reference in its entirety.

### TECHNICAL FIELD

The present disclosure relates to a raw material supply device and a raw material supply method.

### BACKGROUND

There is known a technique in which, after a solid raw material is dissolved in a solvent and sprayed into a processing chamber, an interior of the processing chamber is heated to remove the solvent so that the solid raw material remains, and then the interior of the processing chamber is heated to sublimate the solid raw material and to generate a corresponding gas (see, for example, Patent Document 1).

### PRIOR ART DOCUMENTS

### Patent Documents

Patent Document 1: Japanese Patent Laid-Open Publication No. 2004-115831

The present disclosure provides a technique capable of suppressing a fluctuation in an amount of sublimation of a solid raw material.

### SUMMARY

A raw material supply device according to an embodiment of the present disclosure generates a reactive gas from a solution obtained by dissolving a solid raw material in a solvent or a dispersion obtained by dispersing the solid raw material in a dispersion medium. The raw material supply device includes: a container configured to store the solution or the dispersion; an injector configured to inject the solution or the dispersion into the container; an exhaust port configured to evacuate an interior of the container; and a filter provided in the container and configured to partition the interior of the container into a plurality of regions including a first region in which the injector is provided and a second region in which the exhaust port is provided.

According to the present disclosure, it is possible to suppress a fluctuation in an amount of sublimation of a solid raw material.

### BRIEF DESCRIPTION OF DRAWINGS

FIG. 1 is a view illustrating an example of a raw material supply system according to an embodiment.

FIG. 2 is a view (1) for explaining an operation of the raw material supply system of FIG. 1.

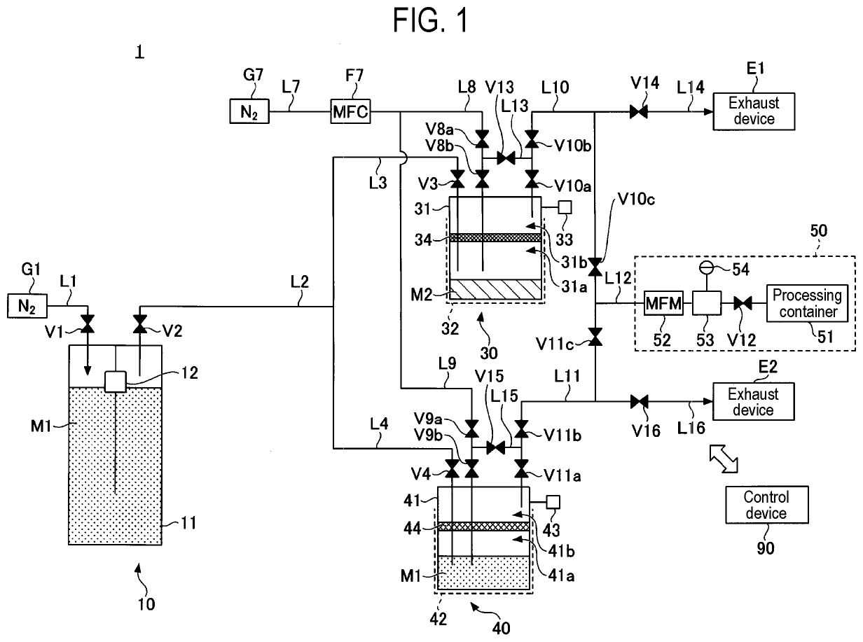

FIG. 1.

FIG. 3 is a view (2) for explaining an operation of the raw material supply system of FIG. 4 is a view (1) for explaining a filling process.

FIG. 5 is a view (2) for explaining the filling process.

FIG. 6 is a view (1) for explaining a drying process.

FIG. 7 is a view (2) for explaining the drying process.

FIG. 8 is a view (1) for explaining a sublimation process.

FIG. 9 is a view (2) for explaining the sublimation process.

### DETAILED DESCRIPTION

Hereinafter, non-limiting exemplary embodiments of the present disclosure will be described with reference to the accompanying drawings. In all the accompanying drawings, the same or corresponding members or components will be denoted by the same or corresponding reference numerals, and redundant descriptions will be omitted.

(Raw Material Supply System)

A raw material supply system of an embodiment will be described with reference to FIG. 1. FIG. 1 is a view illustrating an example of a raw material supply system according to an embodiment.

A raw material supply system 1 is a system which generates a reactive gas by sublimating a second solid raw material formed by removing, from a solution obtained by dissolving a first solid raw material in a solvent (hereinafter, also simply referred to as “solution”), the solvent, and performs film formation in a processing apparatus by using the generated reactive gas.

The first solid raw material is not particularly limited, but may be, for example, an organic metal complex containing a metal element such as strontium (Sr), molybdenum (Mo), ruthenium (Ru), zirconium (Zr), hafnium (Hf), tungsten (W), or aluminum (Al), or a chloride containing a metal element such as tungsten (W) or aluminum (Al). The solvent may be, for example, hexane as long as the first solid raw material can be dissolved in the solvent to form the solution.

The raw material supply system 1 includes a raw material source 10, raw material supply devices 30 and 40, a processing apparatus 50, and a control device 90.

The raw material source 10 supplies a solution M1 to the raw material supply devices 30 and 40. The raw material source 10 is disposed in, for example, a sub-fabrication facility. In the present embodiment, the raw material source 10 includes a tank 11 and a float sensor 12. The tank 11 is filled with the solution M1. The float sensor 12 detects an amount of the solution M1 filled in the tank 11.

One end of a pipe L1 is inserted into the raw material source 10 from above the tank 11. The other end of the pipe L1 is connected to a carrier gas source G1, and a carrier gas is supplied from the source G1 into the tank 11 via the pipe L1. The carrier gas may be, for example, an inert gas such as nitrogen (N₂) or argon (Ar). A valve V1 is interposed in the pipe L1. When the valve V1 is opened, the carrier gas is supplied from the source G1 to the raw material source 10, and when the valve V1 is closed, the supply of the carrier gas from the source G1 to the raw material source 10 is cut off. In addition, the pipe L1 may be provided with a flow rate controller (not illustrated), an additional valve, or the like that controls a flow rate of the carrier gas flowing through the pipe L1.

The raw material source 10 is connected to the raw material supply device 30 via pipes L2 and L3 and supplies the solution M1 to the raw material supply device 30 via the pipes L2 and L3. Valves V2 and V3 are interposed in the pipes L2 and L3, respectively. When the valves V2 and V3 are opened, the solution M1 is supplied from the raw material source 10 to the raw material supply device 30, and when the valves V2 and V3 are closed, the supply of the solution M1 from the raw material source 10 to the raw material supply device 30 is cut off. The pipe L3 may be provided with a flow rate controller (not illustrated) configured to control a flow rate of the solution M1 flowing through the pipe L3, an additional valve, or the like.

In addition, the raw material source 10 is connected to the raw material supply device 40 via the pipes L2 and L4 and supplies the solution M1 to the raw material supply device 40 via the pipes L2 and L4. A valve V4 is interposed in the pipe L4. When the valves V2 and V4 are opened, the solution M1 is supplied from the raw material source 10 to the raw material supply device 40, and when the valves V2 and V4 are closed, the supply of the solution M1 from the raw material source 10 to the raw material supply device 40 is cut off. The pipe L4 may be provided with a flow rate controller (not illustrated) configured to control a flow rate of the solution M1 flowing through the pipe L4, an additional valve, or the like.

The raw material supply device 30 stores the solution M1 transported from the raw material source 10. In the present embodiment, the raw material supply device 30 includes a container 31, a heater 32, a pressure gauge 33, and a filter 34. The container 31 stores the solution M1 transported from the raw material source 10. The heater 32 heats a solid raw material (hereinafter, referred to as a “second solid raw material M2”) formed by removing the solvent from the solution M1, thereby sublimating the second solid raw material M2 to generate a reactive gas. The heater 32 may be, for example, a heater disposed to cover a bottom portion and an outer periphery of the container 31. The heater 32 is configured to be capable of heating an interior of the container 31 to a temperature that can sublimate the second solid raw material M2 to generate the reactive gas. The pressure gauge 33 detects an internal pressure of the container 31. The detected internal pressure of the container 31 is transmitted to the control device 90, and the control device 90 controls opening and closing of various valves based on the internal pressure. For example, when the internal pressure becomes higher than a predetermined pressure, the control device 90 closes the valve V3 to prevent the solution M1 from being excessively supplied to the container 31. The filter 34 is provided substantially horizontally inside the container 31 and partitions the interior of the container 31 into a first region 31a and a second region 31b. A tip end of the pipe L3 is inserted into the first region 31a. As a result, an interior of the pipe L3 is in communication with the first region 31a. The second region 31b is located above the first region 31a. The filter 34 may be made of a material that permeates the reactive gas and traps the second solid raw material M2 and impurities such as particles, and is made of, for example, a porous material. The porous material may be, for example, a porous metal material such as a sintered body of stainless steel, or a porous ceramic material.

One end of a pipe L8 is inserted into the raw material supply device 30 from above the container 31. The one end of the pipe L8 is inserted into, for example, the first region 31a. As a result, an interior of the pipe L8 is in communication with the first region 31a. However, the one end of the pipe L8 may be inserted into the second region 31b. The other end of the pipe L8 is connected to a carrier gas source G7 via a pipe L7, and a carrier gas is supplied from the source G7 into the container 31 via the pipes L7 and L8. The carrier gas may be, for example, an inert gas such as N₂ or Ar. Valves V8a and V8b are interposed in the pipe L8 in order from a side of the source G7. When the valves V8a and V8b are opened, the carrier gas is supplied from the source G7 to the raw material supply device 30, and when the valves V8a and V8b are closed, the supply of the carrier gas from the source G7 to the raw material supply device 30 is cut off. A flow rate controller F7 configured to control a flow rate of the carrier gas flowing through the pipe L7 is interposed in the pipe L7. In the present embodiment, the flow rate controller F7 is a mass flow controller (MFC).

The raw material supply device 30 is connected to the processing apparatus 50 via pipes L10 and L12 and supplies the reactive gas to the processing apparatus 50 via the pipes L10 and L12. A tip end of the pipe L10 is inserted into the second region 31b in the container 31. As a result, an interior of the pipe L10 is in communication with the second region 31b. Valves V10a to V10c are interposed in the pipe L10 in order from a side of the raw material supply device 30. When the valves V10a to V10c are opened, the reactive gas is supplied from the raw material supply device 30 to the processing apparatus 50, and when the valves V10a to V10c are closed, the supply of the reactive gas from the raw material supply device 30 to the processing apparatus 50 is cut off.

One end of a pipe L13 is connected between the valve V10a and the valve V10b of the pipe L10. The other end of the pipe L13 is connected between the valve V8a and the valve V8b of the pipe L8. The pipe L13 functions as a bypass pipe that connects the pipe L8 and the pipe L10 to each other without passing through the raw material supply device 30. A valve V13 is interposed in the pipe L13. When the valve V13 is opened, the pipe L8 and the pipe L10 are in communication with each other, and when the valve V13 is closed, the communication between the pipe L8 and the pipe L10 is cut off.

One end of a pipe L14 is connected between the valve V10b and the valve V10c of the pipe L10. The other end of the pipe L14 is connected to an exhaust device E1 such as a vacuum pump. A valve V14 is interposed in the pipe L14. When the valve V14 is opened in a state in which the valves V10a and V10b are opened, the interior of the container 31 is evacuated, and the solvent can be removed from the solution M1 stored in the container 31. When the valve V14 is closed, it is possible to stop the removal of the solvent from the solution M1 stored in the container 31.

The raw material supply device 40 stores the solution M1 transported from the raw material source 10. The raw material supply device 40 is provided in parallel with the raw material supply device 30. In the present embodiment, the raw material supply device 40 includes a container 41, a heater 42, a pressure gauge 43, and a filter 44. The container 41 stores the solution M1 sent from the raw material source 10. The heater 42 heats the second solid raw material M2 formed by removing the solvent from the solution M1, thereby sublimating the second solid raw material M2 to generate a reactive gas. The heater 42 may be, for example, a heater disposed to cover a bottom portion and an outer periphery of the container 41. The heater 42 is configured to be capable of heating an interior of the container 41 to a temperature that can sublimate the second solid raw material M2 to generate the reactive gas. The pressure gauge 43 detects an internal pressure of the container 41. The detected internal pressure of the container 41 is transmitted to the control device 90, and the control device 90 controls opening and closing of various valves based on the internal pressure. For example, when the internal pressure becomes higher than a predetermined pressure, the control device 90 closes the valve V4 to prevent the solution M1 from being excessively supplied to the container 41. The filter 44 is provided substantially horizontally inside the container 41 and partitions the interior of the container 41 into a first region 41a and a second region 41b. A tip end of the pipe L4 is inserted into the first region 41a. As a result, an interior of the pipe L4 is in communication with the first region 41a. The second region 41b is located above the first region 41a. The filter 44 is made of, for example, the same material as the filter 34.

One end of a pipe L9 is inserted into the raw material supply device 40 from above the container 41. The one end of the pipe L9 is inserted into the first region 41a. As a result, an interior of the pipe L9 is in communication with the first region 41a. However, the one end of the pipe L9 may be inserted into the second region 41b. The other end of the pipe L9 is connected to the carrier gas source G7 via the pipe L7, and the carrier gas is supplied from the source G7 into the container 41 via the pipes L7 and L9. The carrier gas may be, for example, an inert gas such as N₂ or Ar. Valves V9a and V9b are interposed in the pipe L9 in order from a side of the source G7. When the valves V9a and V9b are opened, the carrier gas is supplied from the source G7 to the raw material supply device 40, and when the valves V9a and V9b are closed, the supply of the carrier gas from the source G7 to the raw material supply device 40 is cut off.

The raw material supply device 40 is connected to the processing apparatus 50 via a pipe L11 and the pipe L12 and supplies the reactive gas to the processing apparatus 50 via the pipes L11 and L12. A tip end of the pipe L11 is inserted into the second region 41b in the container 41. As a result, an interior of the pipe L11 is in communication with the second region 41b. Valves V11a to V11c are interposed in the pipe L11. When the valves V11a to V11c are opened, the reactive gas is supplied from the raw material supply device 40 to the processing apparatus 50, and when the valves V11a to V11c are closed, the supply of the reactive gas from the raw material supply device 40 to the processing apparatus 50 is cut off.

One end of a pipe L15 is connected between the valve V11a and the valve V11b of the pipe L11. The other end of the pipe L15 is connected between the valve V9a and the valve V9b of the pipe L9. The pipe L15 functions as a bypass pipe that connects the pipe L9 and the pipe L11 without passing through the raw material supply device 40. A valve V15 is interposed in the pipe L15. When the valve V15 is opened, the pipe L9 and the pipe L11 are in communication with each other, and when the valve V15 is closed, the communication between the pipe L9 and the pipe L11 is cut off.

One end of a pipe L16 is connected between the valve V11b and the valve V11c of the pipe L11. The other end of the pipe L16 is connected to an exhaust device E2 such as a vacuum pump. A valve V16 is interposed in the pipe L16. When the valve V16 is opened in a state in which the valves V11a and V11b are opened, the interior of the container 41 is evacuated, and the solvent can be removed from the solution M1 stored in the container 41. When the valve V16 is closed, it is possible to stop the removal of the solvent from the solution M1 stored in the container 41.

The processing apparatus 50 is connected to the raw material supply device 30 via the pipes L10 and L12, and the processing apparatus 50 is supplied with the reactive gas generated by heating and sublimating the second solid raw material M2 in the raw material supply device 30. In addition, the processing apparatus 50 is connected to the raw material supply device 40 via the pipes L11 and L12, and the processing apparatus 50 is supplied with the reactive gas generated by heating and sublimating the second solid raw material M2 in the raw material supply device 40.

The processing apparatus 50 executes various processes such as a film forming process on a substrate such as a semiconductor wafer by using the reactive gas supplied from the raw material supply devices 30 and 40. In the present embodiment, the processing apparatus 50 includes a processing container 51, a flow meter 52, a storage tank 53, a pressure sensor 54, and a valve V12. The processing container 51 accommodates one or more substrates. In the present embodiment, the flow meter 52 is a mass flow meter (MFM). The flow meter 52 is interposed in the pipe L12 and measures a flow rate of the reactive gas flowing through the pipe L12. The storage tank 53 temporarily stores the reactive gas. Since the storage tank 53 is provided, it is possible to supply a large flow rate of the reactive gas into the processing container 51 in a short time. The storage tank 53 is also referred to as a “buffer tank” or a “fill tank.” The pressure sensor 54 detects a pressure in the storage tank 53. The pressure sensor 54 is, for example, a capacitance manometer. A valve V12 is interposed in the pipe L12. When the valve V12 is opened, the reactive gas is supplied from the raw material supply devices 30 and 40 to the processing container 51, and when the valve V12 is closed, the supply of the reactive gas from the raw material supply devices 30 and 40 to the processing container 51 is cut off.

The control device 90 controls respective components of the raw material supply system 1. For example, the control device 90 controls operations of the raw material source 10, the raw material supply devices 30 and 40, the processing apparatus 50, and the like. The control device 90 controls the opening and closing of various valves. The control device 90 may be, for example, a computer.

(Operations of Raw Material Supply System)

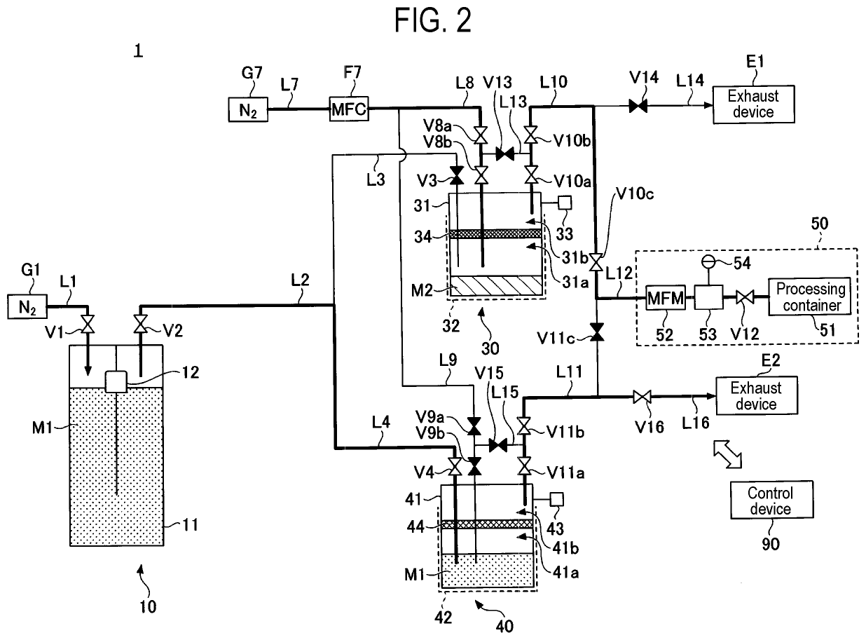

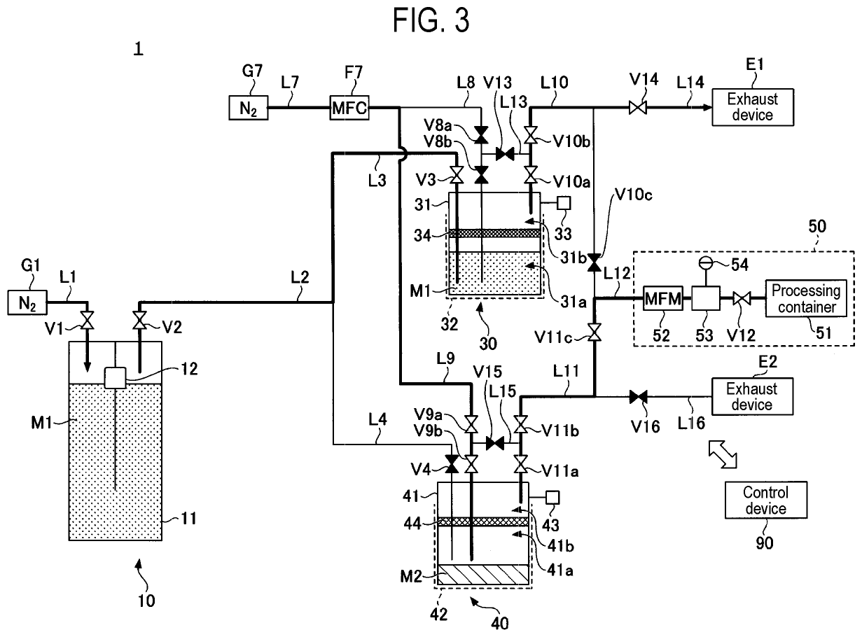

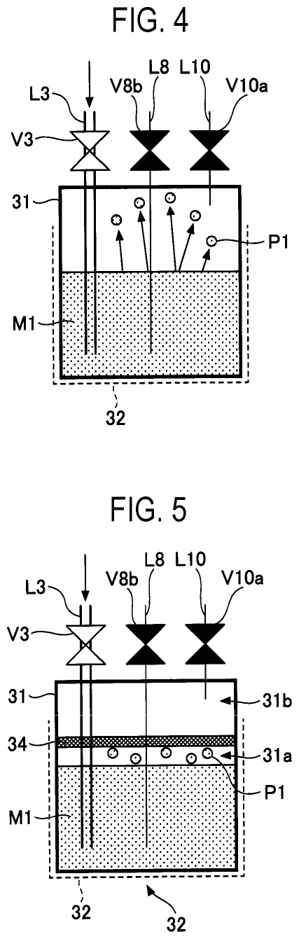

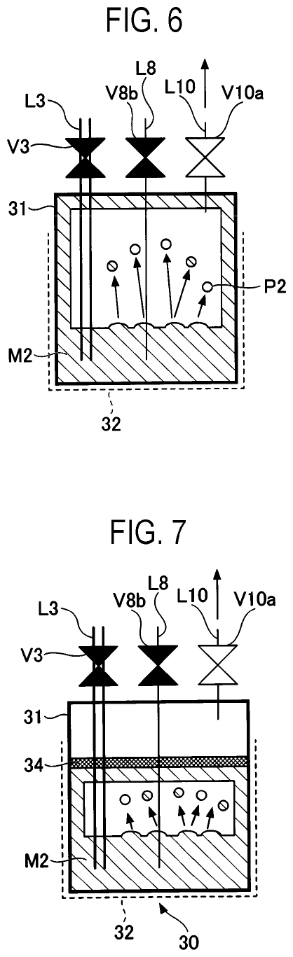

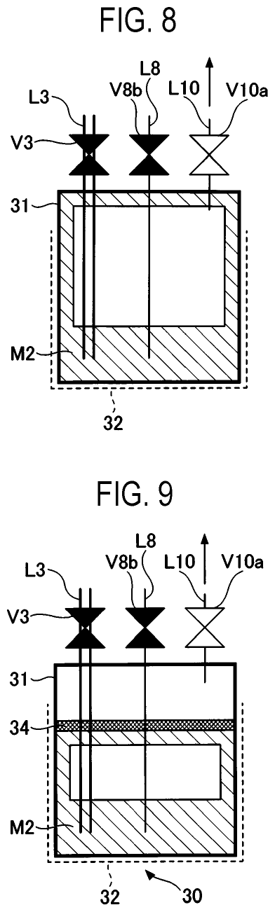

An example of operations of the raw material supply system 1 (a raw material supply method) will be described with reference to FIGS. 2 and 3. In the raw material supply system 1, the control device 90 controls opening and closing of various valves to supply the reactive gas from one of the two raw material supply devices 30 and 40 provided in parallel to the processing apparatus 50, and to fill the other raw material supply device with the solid raw material. Hereinafter, an example of the operations of the raw material supply system 1 will be described in detail.

First, with reference to FIG. 2, a case where the raw material supply device 30 supplies the reactive gas to the processing apparatus 50 and the raw material supply device 40 is filled with the solid raw material will be described. FIG. 2 is a view for explaining an operation of the raw material supply system 1 of FIG. 1. In FIG. 2, the pipes through which the carrier gas, the solution M1, and the reactive gas flow are indicated by thick solid lines, and the pipes through which the carrier gas, the solution M1, and the reactive gas do not flow are indicated by thin solid lines. In addition, in FIG. 2, a state in which the valves are opened is indicated by a white symbol, and a state in which the valves are closed is indicated by a black symbol. The raw material supply system 1 will be described assuming that all of the valves are closed in an initial state as illustrated in FIG. 1, and that the raw material supply device 30 stores the second solid raw material M2.

The control device 90 controls the heater 32 of the raw material supply device 30 to heat and sublimate the second solid raw material M2 in the container 31, thereby generating the reactive gas (a sublimation process). In addition, the control device 90 opens the valves V8a, V8b, V10a to V10c, and V12. As a result, the carrier gas is injected from the source G7 into the container 31 of the raw material supply device 30 via the pipes L7 and L8, and the reactive gas generated in the container 31 is supplied to the processing container 51 via the pipes L10 and L12 together with the carrier gas.

In addition, the control device 90 opens the valves V1, V2, and V4, as illustrated in FIG. 2. As a result, the carrier gas is supplied from the source G1 to the raw material source 10, and the solution M1 is transported from the raw material source 10 to the raw material supply device 40 via the pipes L2 and L4. As a result, the solution M1 is stored in the container 41 of the raw material supply device 40 (a filling process).

Subsequently, the control device 90 opens the valves V11a, V11b, and V16. As a result, the interior of the container 41 of the raw material supply device 40 is evacuated by the exhaust device E2, so that the solvent is removed from the solution M1 in the container 41, and the second solid raw material M2 is formed in the container 41 (a drying process). For example, the control device 90 determines whether a predetermined amount of the solution M1 is stored in the container 41 based on the detection value of the float sensor 12, and upon determining that the predetermined amount of the solution M1 is stored in the container 41, the control device 90 opens the valves Vila, V11b, and V16. The predetermined amount is set to, for example, an amount capable of being stored in the container 41 of the raw material supply device 40. When removing the solvent from the solution M1 in the container 41, the control device 90 may control the heater 42 to heat the solution M1 in the container 41 to a predetermined temperature. This facilitates the removal of the solvent. The predetermined temperature is set to be lower than, for example, the temperature for sublimating the second solid raw material M2 to generate a reactive gas. FIG. 2 illustrates a state before the solvent is removed from the solution M1 in the container 41.

Subsequently, with reference to FIG. 3, a case where the raw material supply device 40 supplies the reactive gas to the processing apparatus 50 and the raw material supply device 30 is filled with the solid raw material will be described. FIG. 3 is a view for explaining an operation of the raw material supply system 1. In FIG. 3, the pipes through which the carrier gas, the solution M1, and the reactive gas flow are indicated by thick solid lines, and the pipes through which the carrier gas, the solution M1, and the reactive gas do not flow are indicated by thin solid lines. In addition, in FIG. 3, the state in which the valves are opened is indicated by a white symbol, and the state in which the valves are closed is indicated by a black symbol. In the raw material supply system 1, it is assumed that all of the valves are closed in an initial state, as illustrated in FIG. 1. In addition, as illustrated in FIG. 3, the second solid raw material M2 will be described as being stored in the raw material supply device 40.

The control device 90 controls the heater 42 of the raw material supply device 40 to heat and sublimate the second solid raw material M2 in the container 41, thereby generating the reactive gas (a sublimation process). In addition, the control device 90 opens the valves V9a, V9b, V11a to V11c, and V12. As a result, the carrier gas is injected from the source G7 into the container 41 of the raw material supply device 40 via the pipes L7 and L9, and the reactive gas generated in the container 41 is supplied to the processing container 51 via the pipes L11 and L12 together with the carrier gas.

The control device 90 opens the valves V1, V2, and V3, as illustrated in FIG. 3. As a result, the carrier gas is supplied from the source G1 to the raw material source 10, and the solution M1 is transported from the raw material source 10 to the raw material supply device 30 via the pipes L2 and L3. As a result, the solution M1 is stored in the container 31 of the raw material supply device 30 (a filling process).

Subsequently, the control device 90 opens the valves V10a, V10b, and V14. As a result, the interior of the container 31 of the raw material supply device 30 is evacuated by the exhaust device E1, so that the solvent is removed from the solution M1 in the container 31, and the second solid raw material M2 is formed in the container 31 (a drying process). For example, the control device 90 determines whether a predetermined amount of the solution M1 is stored in the container 31 based on the detection value of the float sensor 12, and upon determining that the predetermined amount of the solution M1 is stored in the container 31, the control device 90 opens the valves V10a, V10b, and V14. The predetermined amount is set to, for example, an amount capable of being stored in the container 31 of the raw material supply device 30. When removing the solvent from the solution M1 in the container 31, the control device 90 may control the heater 32 to heat the solution M1 in the container 31 to a predetermined temperature. This facilitates the removal of the solvent. The predetermined temperature is set to be lower than, for example, the temperature for sublimating the second solid raw material M2 to generate the reactive gas. FIG. 3 illustrates a state before the solvent is removed from the solution M1 in the container 31.

As described above, with the raw material supply system 1, by controlling the opening and closing of valves by the control device 90, the reactive gas is supplied from one of the two raw material supply devices 30 and 40 to the processing apparatus 50, and the other raw material supply device is filled with the solid raw material. As a result, automatic replenishment of the raw material to the raw material supply devices 30 and 40 can be performed, which makes it possible to improve continuous operation capability of the processing apparatus 50 and to improve an operating rate of the processing apparatus 50.

(Operative Effects)

Referring to FIGS. 4 to 9, operative effects of the raw material supply devices 30 and 40 of the embodiment will be described by taking the raw material supply device 30 as an example. The raw material supply device 40 is also similar to the raw material supply device 30.

FIGS. 4 and 5 are views for explaining the filling process. As illustrated in FIG. 4, in the filling process, droplets P1 may be generated when the container 31 is filled with the solution M1 from the tip end of the pipe L3. For example, when the pressure inside the container 31 is high, droplets P1 are easily generated. In contrast, as illustrated in FIG. 5, the raw material supply device 30 of the embodiment includes the filter 34 that partitions the interior of the container 31 into the first region 31a and the second region 31b. Accordingly, when the container 31 is filled with the solution M1 from the tip end of the pipe L3 inserted into the first region 31a, the filter 34 can suppress generation of droplets.

FIGS. 6 and 7 are views for explaining the drying process. As illustrated in FIG. 6, the drying process may cause the solvent to boil as the solvent is removed from the solution M1. When the solvent boils, the second solid raw material M2 scatters over a wide area. Therefore, the second solid raw material M2 may be engaged in the valve V10a and cause an internal leak. In addition, the second solid raw material M2 may adhere to a wide area on an inner wall of the container 31, and an amount of sublimation of the second solid raw material M2 may become unstable when the second solid raw material M2 is sublimated in the sublimation process. In contrast, as illustrated in FIG. 7, the raw material supply device 30 of the embodiment includes the filter 34 that partitions the interior of the container 31 into the first region 31a and the second region 31b. Thus, even when the solvent boils, the second solid raw material M2 is suppressed from being scattered to the valve V10a. Therefore, it is possible to suppress occurrence of the internal leak in the valve V10a.

FIGS. 8 and 9 are views for explaining the sublimation process. As illustrated in FIG. 8, in an initial stage of the sublimation process, the second solid raw material M2, which has adhered extensively to the inner wall of the container 31, and the second solid raw material M2, which has been deposited on a bottom portion of the container 31, are sublimated. Therefore, the amount of sublimation increases. In the middle of the sublimation process, the second solid raw material M2 adhered to the inner wall of the container 31 disappears, and only the second solid raw material M2 deposited on the bottom portion of the container 31 sublimes. Therefore, the amount of sublimation is reduced compared to the initial stage. As described above, when the second solid raw material M2 is adhered to a wide area of the inner wall of the container 31, the amount of sublimation in the sublimation process fluctuates significantly. Therefore, a supply flow rate of the reactive gas becomes unstable in the sublimation process. In contrast, as illustrated in FIG. 9, the raw material supply device 30 of the embodiment includes the filter 34 that partitions the interior of the container 31 into the first region 31a and the second region 31b. Thus, the area where the second solid raw material M2 adheres in the drying process becomes narrow, so that the difference in the amount of sublimation between the initial stage and the middle stage of the sublimation process becomes small. That is, it is possible to suppress a fluctuation in the amount of sublimation in the sublimation process. Therefore, it is possible to stably supply the reactive gas in the sublimation process.

In the above-described embodiment, the pipes L3 and L4 are an example of an injector, the pipes L10 and L11 are an example of an exhaust port, and the control device 90 is an example of a controller.

It should be considered that the embodiment disclosed herein is exemplary in all respects and not restrictive. The embodiment described above may be omitted, replaced, or modified in various forms without departing from the scope and spirit of the appended claims.

In the above-described embodiment, the case where the raw material supply system 1 includes two raw material supply devices 30 and 40 provided in parallel, has been described, but the present disclosure is not limited thereto. For example, one raw material supply device may be provided, or three or more raw material supply devices may be provided in parallel. However, from the viewpoint of eliminating a downtime associated with filling the solution M1, two or more raw material supply devices may be provided.

In the above-described embodiment, the system, in which the second solid raw material M2 formed by removing the solvent from the solution M1 is sublimated to generate the reactive gas and the generated reactive gas is used to form a film in the processing apparatus 50, has been described. However, the present disclosure is not limited thereto. For example, instead of the solution M1, a dispersion such as a slurry obtained by dispersing a first solid raw material in a dispersion medium, or a colloidal solution obtained by dispersing a first solid raw material in a dispersion medium may also be used. For example, by using the colloidal solution, it is possible to fill a precursor having a higher concentration compared to the case of using the solution M1 or the slurry. The dispersion includes a slurry and a colloid as subordinate concepts. The slurry is also referred to as a suspension. The colloid includes a colloidal solution as a subordinate concept. The colloidal solution is also referred to as a sol.

The present international application claims priority based on Japanese Patent Application No. 2020-154854 filed on Sep. 15, 2020, the disclosure of which is incorporated herein in its entirety by reference.

### EXPLANATION OF REFERENCE NUMERALS

30, 40: raw material supply device, 31, 41: container, 31a, 41a: first region, 31b, 41b: second region, 32, 42: heater, 34, 44: filter, 50: processing apparatus, E1, E2: exhaust device, L3, L4: pipe, L10, L11: pipe

1-9. (canceled)

10. A raw material supply device that generates a reactive gas from a solution obtained by dissolving a solid raw material in a solvent or a dispersion obtained by dispersing the solid raw material in a dispersion medium, the raw material supply device comprising:
a container configured to store the solution or the dispersion;
an injector configured to inject the solution or the dispersion into the container;
an exhaust port configured to evacuate an interior of the container; and
a filter provided in the container and configured to partition the interior of the container into a plurality of regions including a first region in which the injector is provided and a second region in which the exhaust port is provided.

11. The raw material supply device of claim 10, wherein the filter is provided substantially horizontally within the container.

12. The raw material supply device of claim 11, wherein the filter is made of a porous material.

13. The raw material supply device of claim 12, wherein the second region is located above the first region.

14. The raw material supply device of claim 13, wherein the exhaust port is connected to a processing apparatus.

15. The raw material supply device of claim 14, wherein the exhaust port is connected to an exhaust device configured to evacuate the interior of the container.

16. The raw material supply device of claim 15, wherein the dispersion is a slurry or colloidal solution.

17. The raw material supply device of claim 16, further comprising a heater configured to heat the container.

18. The raw material supply device of claim 10, wherein the filter is made of a porous material.

19. The raw material supply device of claim 10, wherein the second region is located above the first region.

20. The raw material supply device of claim 10, wherein the exhaust port is connected to a processing apparatus.

21. The raw material supply device of claim 10, wherein the exhaust port is connected to an exhaust device configured to evacuate the interior of the container.

22. The raw material supply device of claim 10, wherein the dispersion is a slurry or colloidal solution.

23. The raw material supply device of claim 10, further comprising a heater configured to heat the container.

24. A raw material supply method comprising:
injecting a solution obtained by dissolving a first solid raw material in a solvent or a dispersion obtained by dispersing the first solid raw material in a dispersion medium into a first region partitioned by a filter within a container;
forming a second solid raw material by removing the solvent or the dispersion medium from the solution or the dispersion injected into the first region; and
generating a reactive gas by heating and sublimating the second solid raw material, and supplying the reactive gas to a processing apparatus from a second region partitioned by the filter within the container.
